(19) United States
(12) Patent Application Publication
(10) Pub. No.: US 2011/0109340 A1
(43) Pub. Date: May 12, 2011

(54) Interface Adapter For Connecting With A Test Probe

(75) Inventors: Bear Xiong, Shanghai (CN); Super Cui, Shanghai (CN)

(73) Assignee: Semiconductor Manufacturing International (Shanghai) Corporation, Shanghai (CN)

(21) Appl. No.: 12/787,852

(22) Filed: May 26, 2010

(30) Foreign Application Priority Data
Nov. 10, 2009 (CN) 200920212189.5

(51) Int. Cl. G01R 31/02

(52) U.S. Cl. 324/756.04; 324/757.02

(57) ABSTRACT

A interface adapter comprising a connecting board having the first ports and the second ports, the first ports being electrically connected with the second ports; a pin header having the first pins and the second pins, the first pins passing through the first ports, the second pins being connected with the second ports; a female header having openings for receiving the first pins, the connecting board being located between the pin header and the female header. The second pin is designed to O-shape or U-shape for providing enough position to connecting the test probe, preventing from disengagement of the chip from the test card.

### CROSS REFERENCE TO RELATED APPLICATIONS

The present application claims the priority of Chinese Patent Application No. 200920212189.5, entitled “Chip test Interface Adapter”, and filed Nov. 10, 2009, the entire disclosure of which is incorporated herein by reference.

### BACKGROUND OF THE INVENTION

1. Field of the Invention

The present invention relates to an interface adapter, and particularly relates to an interface adapter for connecting a test probe.

2. Description of Prior Art

With increasing density and complexity of integrated circuit, the integrated circuit is widely applied in many fields. The integrated circuit industry has become very important in modern electronics industry. To ensure the quality of integrated circuit chip, a chip test is used for checking defect and finding solution. Consequently, a connected plug module for connecting a test card with a signal generator is published on U.S. Pat. No. 7,322,837.

However, the electronic component of integrated circuit can be damaged due to its high density and small dimension. It is a burning question for test technician that how to electrically connect a chip to be test and a test card, and to generate stable test signal between them.

Referring to FIG. 1, a conventional chip test system is shown. The conventional chip test system includes a test card 1, an oscillograph 2 and a chip 3 to be tested. The test card 1 comprising a pin header 11 having pins and a test module is used to test the chip 3, generate a test sign, and feedback the test sign to an oscillograph 2. The oscillograph 2 comprising a test probe 21 is used to inspect the test sign. A connect unit comprising a female header 31 having opening is used to connect the test card 1 to the chip 3. The openings of the female header 31 are used to receive the pins of the pin header 11. The test probe 21 is used to hook the pins of the pin header 11 to connect oscillograph 2 to test card 1.

Referring to FIG. 2, the interconnection of the pin header 11, the female header 31 and the test probe 21 is shown. The test probe 21 hooks the pins of the pin header 11 with hook nib to connect oscillograph 2 to the test card 1. The pin header 11 is inserted in the female header 31 to connect the test card 1 to the connect unit. It should be known that the length of the pins of the pin header 11 is less than 1 cm. It will take a half the length of the pins of the pin header 11 when the test probe 21 hooked with the pins of the pin header 11. Thus the length of the pins of the pin header 11 inserted in the female header 31 is short. The pin header 11 can disengage from the female header 31 during chip test. When two or more test probes 21 are hooked with one pin header 11, the problem of pin header disengaging from the female header 31 is obvious.

### SUMMARY OF THE INVENTION

An object of the present invention is to provide an interface adapter for connecting a test probe so as to prevent disengagement of the pin header from the female header during chip test.

To achieve the object, an interface adapter is provided. The interface adapter includes: a connecting board, a pin header having first pins and second pins, and a female header. The connecting board has first ports and second ports electrically connected with the first ports. The first pins pass though the first ports, and the second pins are connected with the second ports. The female header has openings for receiving the first pins. The connecting board is located between the pin header and the female header.

According to one embodiment, the second pins are designed to O-shape or U-shape. When the interface adapter is used for electrically connecting with the test probe, the second pin provide enough space to connect one or more test probe, the issues of lose or loose of the chip from the test card is prevented.

### BRIEF DESCRIPTION OF THE DRAWINGS

FIG. 1 is a schematic diagram of prior chip test system.

FIG. 2 is a schematic diagram of prior chip test system used for connecting with a test probe.

FIG. 3 illustrates an exemplary top perspective view of an interface adapter.

FIG. 4 is a cross-sectional view taken from the line 4-4 in FIG. 3.

FIG. 5. is a cross-sectional view of the interface adapter used for connecting with the test probe.

FIG. 6. is a cross-sectional view of the O-shaped second pin.

FIG. 7 is a cross-sectional view of a second interface adapter.

FIG. 8 is a cross-sectional view of the second interface adapter used for connecting with the test probe.

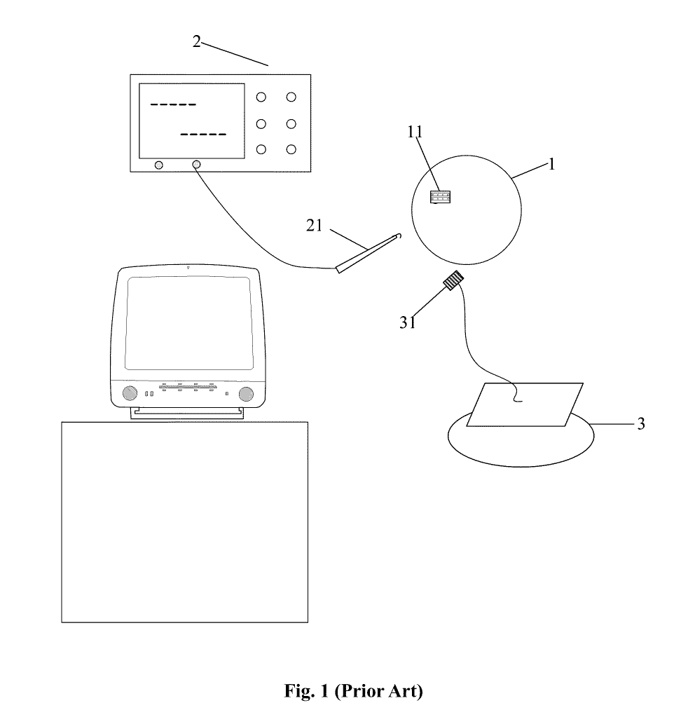

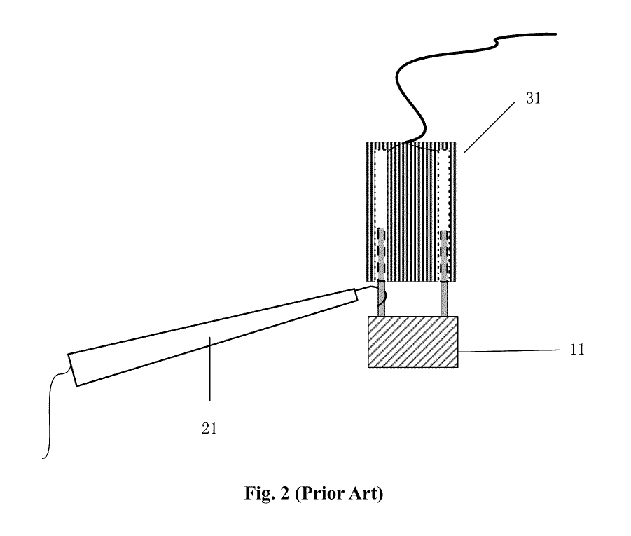

### DETAILED DESCRIPTION OF THE EMBODIMENTS

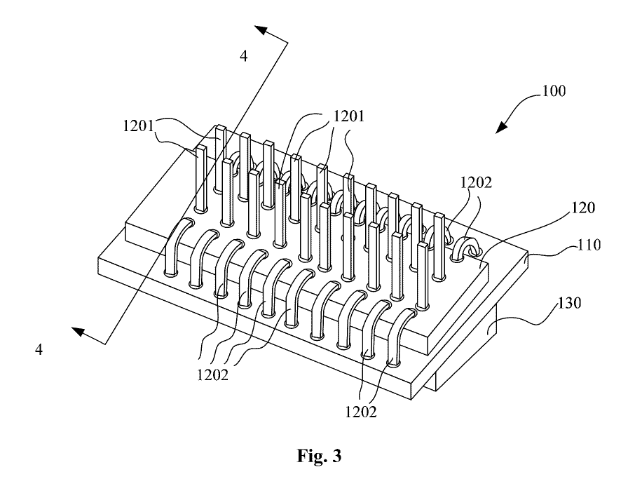

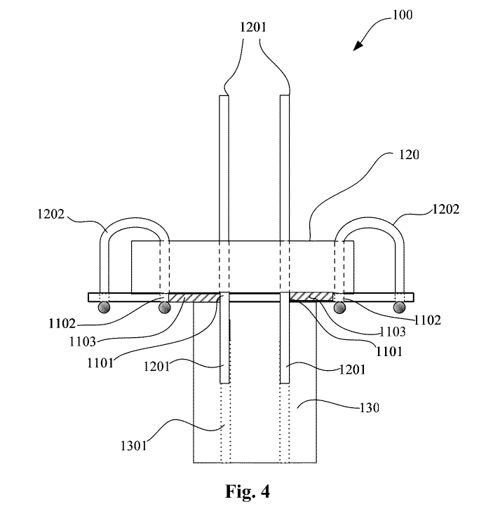

Referring to FIGS. 3 and 4, an interface adapter 100 in accordance with a first embodiment of present invention includes a connecting board 110, a pin header 120, and a female header 130. The pin header 120 includes first pins 1201 and second pins 1202. The female header 130 has openings 1301 for receiving the first pins 1201 of the pin header 120. The connecting board 110 includes first ports 1101 and second ports 1102.

In this embodiment, the connecting board 110 is a printed circuit board (PCB). The connecting board 110 includes twenty first ports 1101 and twenty second ports 1102 The female header 130 has twenty openings 1301. Each of the first pins 1201 is inserted through one relative first port 1101 and into one relative opening 1301 for providing electrical connectivity with the relative first port and the relative opening. In this way, the present invention can be manufactured according to an existing standard, thereby reducing cost. Each of the second pins 1202 is bended to U-shape for suitably electrical connection with a test probe, and is welded to a relative one of the second ports 1102. All the second pins 1202 are located at both sides of the pin header 120 and are mounted on the connecting board 110. A plurality of copper lines 1103 are formed in the connecting board 110, and each of the copper lines 1103 electrically connects a relative one of the first ports 1101 with a relative one of the second ports 1102.

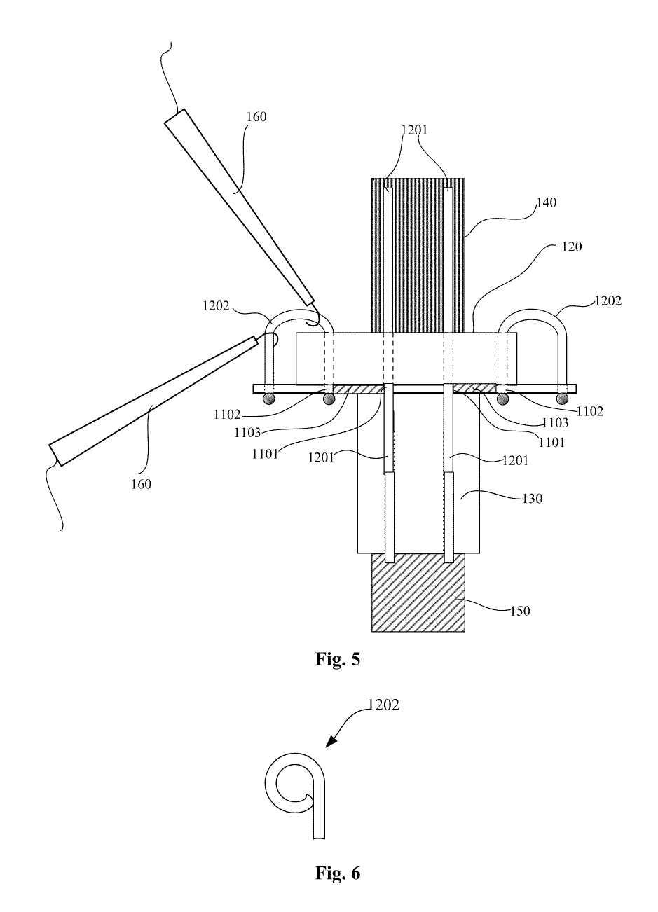

Referring to FIG. 5, the interface adapter 100 (shown in FIG. 4) is used to connect a test card 140 and a chip 150 to be tested. The pin header 120 is connected with the test card 140. The female header 130 is connected with the chip 150 to be test. In this embodiment, the test probe 160 is connected with one of the second pins 1202. The test card 140 generates test signals, and the test signals are transferred, through the female header 130 and the first pin 1201 of the pin header 120, to the second pin 1202. The test probe 160 is adapted to transfer test signals to an oscillograph (not shown) from the second pin 1202. It should be noted that the second pins 1202 are designed and fabricated to U-shape, and therefore have enough position to connect two or more test probes 160, preventing disengagement of the chip 150 from the test card 140.

Alternatively, the second pins 1202 can be O-shaped for stable electrical connection with the test probe, as shown in FIG. 6.

It should be understood that the current invention is not only limited to the illustrated embodiment of the pin header 120 and the female header 130 of FIG. 3, but also could be modified in numerous manners that one of ordinary skilled in the art would recognize. For example, the number of the first pins 1201, the second pins 1202 and openings 1201 is not limited in other embodiments. As one skilled in the art would recognize, the number of the first pins 1201 should match the test card 140, and the number of openings 1201 should match the chip 150 to be test.

The interface adapter 100 described in this embodiment has significant advantage as below: the test probe is not connected with the first pins 1201 directly, which will prevent disengagement of the first pins 1201 from the openings 1301. In this invention, the test probe 160 is connected with the second pins 1202, and the second pins 1202 are designed to U-shape or O-shape and welded on the connecting board 110. Thus the second pins 1202 have enough position to connect two or more test probes 160.

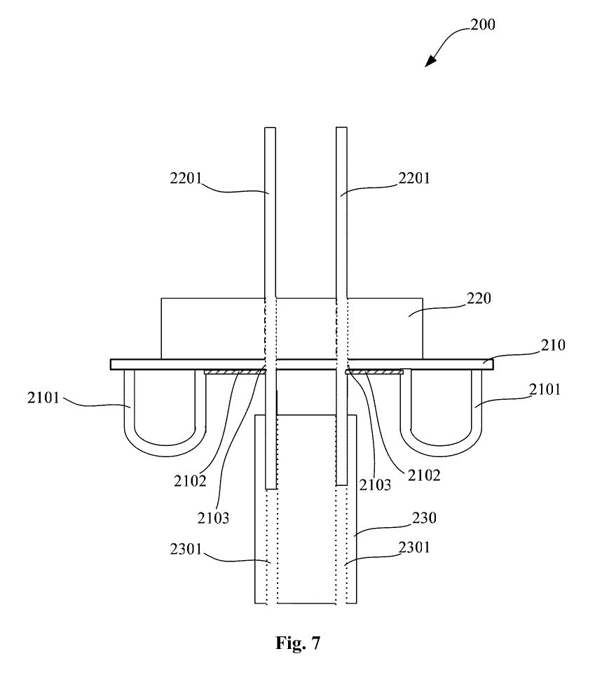

As should be understood, the present invent is not only limited to the illustrated embodiment of the interface adapter 100 of FIG. 3 and FIG. 4, but also could be modified in numerous manners. FIG. 7 is a cross-sectional view of the interface adapter 200 in accordance with a second embodiment of the present invention. The interface adapter 200 includes a connecting board 210 having connecting arms 2101 and ports 2103, a pin header 220 having the first pins 2201, and a female header 230 having openings 2301. A plurality of copper lines 2102 are located at connecting board 210. Each of connecting arms 2101 is electrically connected with a relative one of the ports 2103 by a relative copper line 2102. Each of the first pins 2201 is inserted to a relative one of openings 2301 through one of the ports 2103. The connecting arms 2101 are used to electrically connect with a test probe 260.

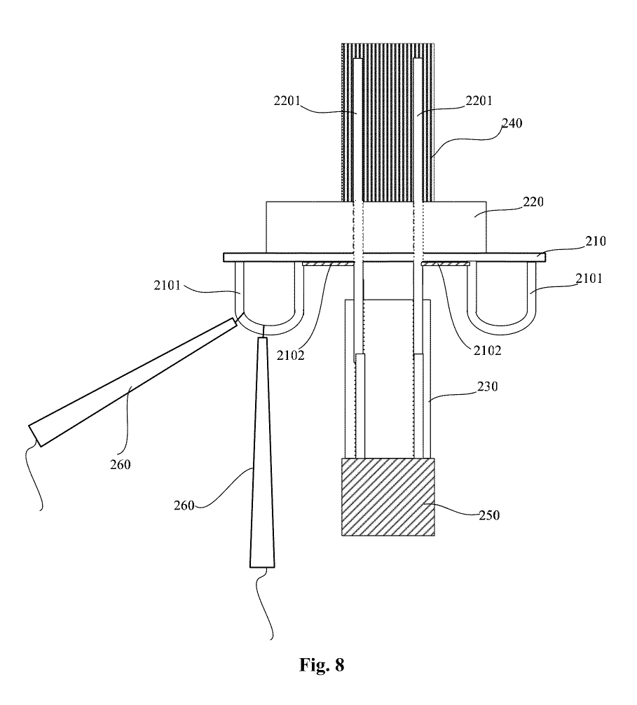

Referring to FIG. 8, the interface adapter 200 is used to connect a test card 240 and a chip 250 to be tested. The pin header 220 is connected with the test card 240, the female header 230 is connected with the chip 250 to be test, and the test probe 260 is connected with one of the connecting arms 2101. In this embodiment, the test card 240 generates test signals along the opening 2301 (shown in FIG. 7) of the female header 230 to first pin 2201 of the pin header 220, the test probe 260 is adapted to provide test signal to the oscillograph (not shown) from one of the connecting arms 2101 to one of first pin 2201.

As should be understood, the connecting arms 2101 in this invention are designed and fabricated to U-shape, and therefore have enough space to connect two or more test probe 260, preventing disengagement of the chip 250 from the test card 240. The connecting arms 2101 can be O-shaped for stable electrical connection with the test probe 260.

In the invention, the test card is electrically connected with the chip to be tested according to the female header and the pin header of the interface adapter, the interface adapter having the connecting arms (or the second pins) to electrically connecting with the test probe, the connecting arms or the second pins are designed to U-shape or O-shape to provide enough position to connect one or more test probe, preventing from disengagement of the chip from the test card.

The present invention has been described in conjunction with the preferred embodiments which, however, do not limit the invention. Various modifications and supplements may be made to the preferred embodiments by the ordinary skill in the art without departing from the spirit and scope of invention as set forth in the appended claims.

What is claimed is:

1. An interface adapter for connecting with a test probe, comprising:
a connecting board having first ports and second ports, the first ports being electrically connected with the second ports;
a pin header having first pins and second pins, the first pins passing through the first ports, the second pins being connected with the second ports; and
a female header having openings for receiving the first pins, the connecting board being located between the pin header and the female header.

2. The interface adapter as claimed in claim 1, wherein the second pins are located at both sides and mounted on the connecting board.

3. The interface adapter as claimed in claim 1, wherein the second pins are bent to O-shape or U-shape and bonded to one of the second ports of the connecting board.

4. The interface adapter as claimed in claim 1, wherein the number of the second pins is twenty, the number of the openings is twenty, and the number of the first pins is twenty.

5. The interface adapter as claimed in claim 1, wherein the connecting board is a printed circuit board.

6. The interface adapter as claimed in claim 1, wherein the first ports are electrically connected with the second ports through copper lines formed in the connecting board.

7. An interface adapter for connecting with a test probe, comprising:
a connecting board having first ports;
a pin header having first pins, the first pins passing through the first ports of the connecting board;
a female header having openings, the opening receiving the first pins, the connecting board being located between the pin header and the female header;
means for electrical connection with the test probe and the first pins.

8. The interface adapter as claimed in claim 7, wherein means for electrical connection with the test probe and the first pins comprises second pins formed on the pin header, the connecting board further having second ports electrically connected with the first ports, the second pins being electrically connected with the second ports.

9. The interface adapter as claimed in claim 7, wherein means for electrical connection with test probe and first pins comprises connecting arms formed on the connecting board.

10. The interface adapter as claimed in claim 9, wherein the connecting arms is O-shape or U-shape.
